(19) United States
(12) Patent Application Publication
(10) Pub. No.: US 2026/0330114 A1
(43) Pub. Date: Oct. 22, 2026

(54) Method and System for Agent-Based Semantic Characterization and Self-Supervised Validation of Electronic Components Using Simulation and Expert Feedback

(71) Applicant: NeuroCAD Inc., Atlanta, GA (US)

(72) Inventor: Matthew Berggren, Marietta, GA (US)

(21) Appl. No.: 19/561,058

(22) Filed: Mar. 9, 2026

Related U.S. Application Data
(63) Continuation-in-part of application No. 19/186,307, filed on Apr. 22, 2025.
(60) Provisional application No. 63/792,155, filed on Apr. 21, 2025.

(51) Int. Cl. G06F 30/3308

(52) U.S. Cl. CPC G06F 30/3308

(57) ABSTRACT

A method for generating a circuit simulator model of an electronic component from an electronic component data sheet comprises receiving, by one or more circuit generation AI agents, the data sheet and a request to generate the model; extracting information from the data sheet; transforming the extracted information into a structured symbolic grammar representation; generating, using that representation, a subcircuit representation of the electronic component and a circuit simulator netlist; executing, with the subcircuit representation and netlist, a circuit simulation to produce a simulated performance curve; verifying, from the simulated performance curve, that the subcircuit representation and netlist accurately reflect the data sheet information; and returning the circuit simulator model comprising the subcircuit representation and the circuit simulator netlist.

### CROSS REFERENCE TO RELATED APPLICATIONS

This application is a continuation-in-part of U.S. patent application Ser. No. 19/186,307, filed Apr. 22, 2025 and titled “Method and System for Agent-Based Semantic Characterization and Self-Supervised Validation of Electronic Components Using Simulation and Expert Feedback”, which claims the benefit under 35 U.S.C. § 119 of U.S. Provisional Patent Application No. 63/792,155, filed Apr. 21, 2025 and titled “Method and System for Extracting and Converting Graphical Curve Data into SPICE-Compatible Simulation Models”, each of which is incorporated herein by reference in its entirety.

### BACKGROUND

Existing workflows for generating circuit simulator models typically rely on manual extraction of component parameters from datasheets. This requires engineers to inspect tables, graphs, and descriptive text to identify key specifications and then hand-code these values into subcircuit definitions and netlist statements for SPICE-class simulators. This manual approach demands extensive domain expertise, is time-consuming, and is prone to transcription errors when confronted with varied datasheet formats and notation conventions.

Semi-automated parsing techniques have been introduced to reduce manual effort. In these methods, developers create regular expressions or template-based scripts tailored to specific datasheet layouts. These scripts extract numeric parameters and automatically populate parameters in predefined netlist templates. While such approaches can speed up model creation for components that conform to known layouts, they lack the flexibility to handle diverse datasheet structures and require continual maintenance as new component families and document styles appear.

Optical character recognition (OCR) combined with natural language processing (NLP) has also been applied to datasheet processing. OCR engines convert documents into raw text, and NLP pipelines perform named-entity recognition to locate parameter names and associated values. The output may consist of key-value pairs representing component specifications. However, subsequent subcircuit assembly and netlist generation remain manual tasks, as these systems do not inherently produce structured symbolic representations or complete simulator-ready netlists.

More recently, machine-learning frameworks have been explored for end-to-end model generation. Neural networks are trained on datasets pairing datasheets with corresponding simulator models, with the aim of inferring component behavior and generating preliminary netlists. Although these methods can produce prototype models, they often lack explicit subcircuit hierarchies, do not generate standardized netlist grammars, and omit automated verification of simulated performance against the original datasheet curves, leaving users to perform manual adjustments.

These varied efforts illustrate the state of the art in circuit simulator model creation. However, these methods rely heavily on manufacturer-supplied SPICE models or tabular metadata and the resulting models often reflect idealized performance or incomplete behavioral boundaries. Therefore, none of these approaches have provided a comprehensive solution that combines the features described in this disclosure.

### SUMMARY

In some aspects, the techniques described herein relate to a method for generating a circuit simulator model of an electronic component from an electronic component data sheet, the method including: receiving, by one or more circuit generation AI agents, the electronic component data sheet and a request to generate the circuit simulator model; extracting, by the one or more circuit generation AI agents, information from the electronic component data sheet; transforming, by the one or more circuit generation AI agents, the information into a structured symbolic grammar representation of the information; generating, by the one or more circuit generation AI agents using the structured symbolic grammar representation of the information, a subcircuit representation of the electronic component; creating, by the one or more circuit generation AI agents using the structured symbolic grammar representation of the information, a circuit simulator netlist; executing, by the one or more circuit generation AI agents using the subcircuit representation of the electronic component and the circuit simulator netlist, a circuit simulation to create a simulated performance curve; verifying, by the one or more circuit generation AI agents using the simulated performance curve, that the subcircuit representation of the electronic component and the circuit simulator netlist accurately represent the information from the electronic component data sheet; and returning, by the one or more circuit generation AI agents, the circuit simulator model including the subcircuit representation of the electronic component and the circuit simulator netlist.

In some aspects, the techniques described herein relate to a system for generating a circuit simulator model of an electronic component from an electronic component data sheet, the system including: one or more processors; and one or more memories storing instructions that, when executed by the one or more processors in response to a request to generate the circuit simulation model, cause one or more circuit generation AI agents to perform operations including: extracting information from the electronic component data sheet; transforming the information into a structured symbolic grammar representation of the information; generating, using the structured symbolic grammar representation of the information, a subcircuit representation of the electronic component; creating, using the structured symbolic grammar representation of the information, a circuit simulator netlist; executing, using the subcircuit representation of the electronic component and the circuit simulator netlist, a circuit simulation to create a simulated performance curve; verifying, using the simulated performance curve, that the subcircuit representation of the electronic component and the circuit simulator netlist accurately represent the information from the electronic component data sheet; and returning the circuit simulator model including the subcircuit representation of the electronic component and the circuit simulator netlist.

In some aspects, the techniques described herein relate to a method including: receiving, by one or more circuit generation AI agents, a request to generate a circuit simulator model of an electronic component, the request including an electronic component data sheet; extracting, by the one or more circuit generation AI agents, information from the electronic component data sheet; generating, by the one or more circuit generation AI agents, a subcircuit representation and a circuit simulator model of the electronic component using a structured symbolic grammar representation of information extracted from the electronic component data sheet; executing, by the one or more circuit generation AI agents using the subcircuit representation of the electronic component and the circuit simulator model, a circuit simulation to create a simulated performance curve; verifying, by the one or more circuit generation AI agents using the simulated performance curve, that the subcircuit representation of the electronic component and the circuit simulator model accurately represent the information from the electronic component data sheet; and returning, by the one or more circuit generation AI agents, the circuit simulator model and the subcircuit representation of the electronic component.

However, this list of features and advantages is not all-inclusive and many additional features and advantages are within the scope of the present disclosure. Moreover, it should be noted that the language used in the present disclosure has been principally selected for readability and instructional purposes, and not to limit the scope of the subject matter disclosed herein.

### BRIEF DESCRIPTION OF THE DRAWINGS

FIG. 1 shows a high-level block diagram illustrating one embodiment of a system for agent-based semantic characterization and self-supervised validation of electronic components using simulation and expert feedback.

FIG. 2 shows a block diagram illustrating one embodiment of a computing device including a characterization application.

FIG. 3 is a flowchart depicting an example method 300 for generating a circuit simulator model of an electronic component from an electronic component data sheet.

### DETAILED DESCRIPTION

The technology described in this disclosure relates to agent-based semantic characterization and self-supervised validation of electronic components using simulation and expert feedback, and particularly to systems and methods for semantic characterization and validation of electronic components using a Mixture-of-Experts (MoE) agent architecture.

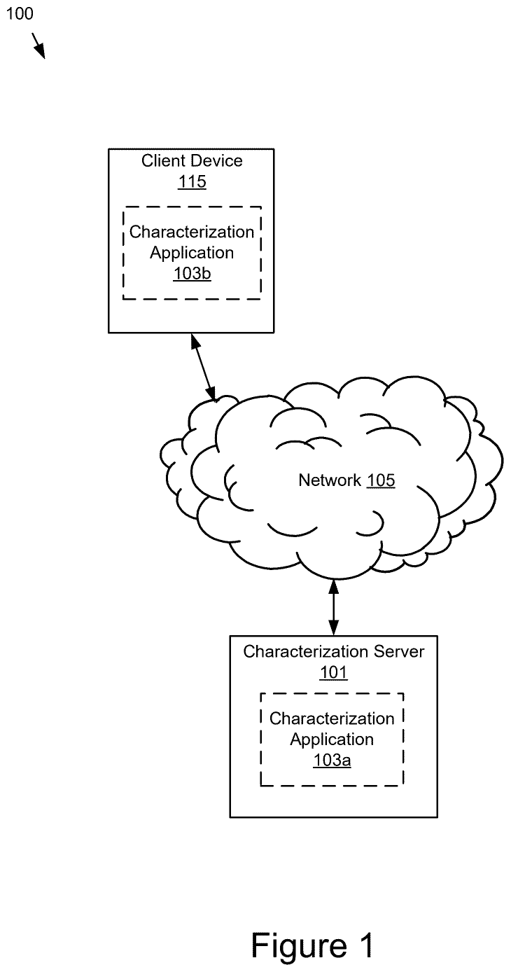

FIG. 1 shows a high-level block diagram illustrating one embodiment of a system 100 for agent-based semantic characterization and self-supervised validation of electronic components using simulation and expert feedback. The illustrated system 100 may have one or more client devices 115 that can be accessed by users and a characterization server 101. In the illustrated embodiment, the entities of the system 100 are communicatively coupled via a network 105.

The network 105 can be a conventional type, wired or wireless, and may have numerous different configurations including a star configuration, token ring configuration or other configurations. Furthermore, the network 105 may include a local area network (LAN), a wide area network (WAN) (e.g., the Internet), and/or other interconnected data paths across which multiple devices may communicate. In some embodiments, the network 105 may be a peer-to-peer network. The network 105 may also be coupled to or include portions of a telecommunications network for sending data in a variety of different communication protocols. In some embodiments, the network 105 may include Bluetooth communication networks or a cellular communications network for sending and receiving data including via short messaging service (SMS), multimedia messaging service (MMS), hypertext transfer protocol (HTTP), direct data connection, WAP, email, etc. Although FIG. 1 illustrates one network 105 coupled to the client device 115 and the characterization server 101, in practice one or more networks 105 can be connected to these entities.

In some embodiments, the system 100 includes a characterization server 101 coupled to the network 105. In some embodiments, the characterization server 101 may be either a hardware server, a software server, or a combination of software and hardware. The characterization server 101 may be, or may be implemented by, a computing device including a processor, a memory, applications, a database, and network communication capabilities. In the example of FIG. 1, the components of the characterization server 101 are configured to implement a characterization application 103a described in more detail below. In one embodiment, the characterization server 101 implements one or more AI agents to perform the semantic characterization and self-supervised validation of electronic components as described in more detail herein. The one or more AI agents may include, among other agents, a content orchestration agent responsible for extraction and normalization of device datasheet information and a simulation-generation agent which produces subcircuit models using a structured grammar and validates them via self-supervised SPICE simulations. The agents collaborate iteratively to construct scenarios reflective of real-world operating conditions, bridging the gap between idealized datasheet curves and actual component behavior. Simulation results are analyzed using clustering algorithms to form a performance taxonomy, enabling deterministic classification, similarity analysis, and circuit design recommendations.

In some embodiments, the characterization server 101 sends and receives data to and from other entities of the system 100 via the network 105. For example, the characterization server 101 receives an electrical component or device datasheet for components characterization from the client device 115. Although only one characterization server 101 is shown in FIG. 1, it should be understood that there may be any number of servers or a server cluster.

The client device 115 may be a computing device that includes a memory, a processor, and input/output devices, for example a laptop computer, a desktop computer, a tablet computer, a smartphone, or any other electronic device capable of accessing network 105. The client device 115 may provide general graphics and multimedia processing for any type of application. The client device 115 includes a display for viewing and interacting with information provided by the characterization server 101. While FIG. 1 illustrates one client device 115, the disclosure applies to a system architecture having one or more client devices 115.

The characterization application 103 may include software and/or logic to provide the functionality agent-based semantic characterization and self-supervised validation of electronic components using simulation and expert feedback. In some embodiments, the characterization application 103 can be implemented using a combination of hardware and software. In other embodiments, the characterization application 103 may be stored and executed on a combination of the client devices 115 and the characterization server 101, or by any one of the client devices 115 or characterization server 101.

In some embodiments, the characterization application 103b acts as a thin-client application with some functionality executed on the client device 115 and additional functionality executed on the characterization server 101 by characterization application 103a. For example, the characterization application 103b on the client device 115 could include software and/or logic for providing a user interface for interacting with characterization application 103a on characterization server 101, and displaying results. A thin-client application 103b may include further functionality described herein with reference to characterization application 103, such as, implementing one or more AI agents. The operation of the characterization application 103 and the functions listed above are described in more detail below.

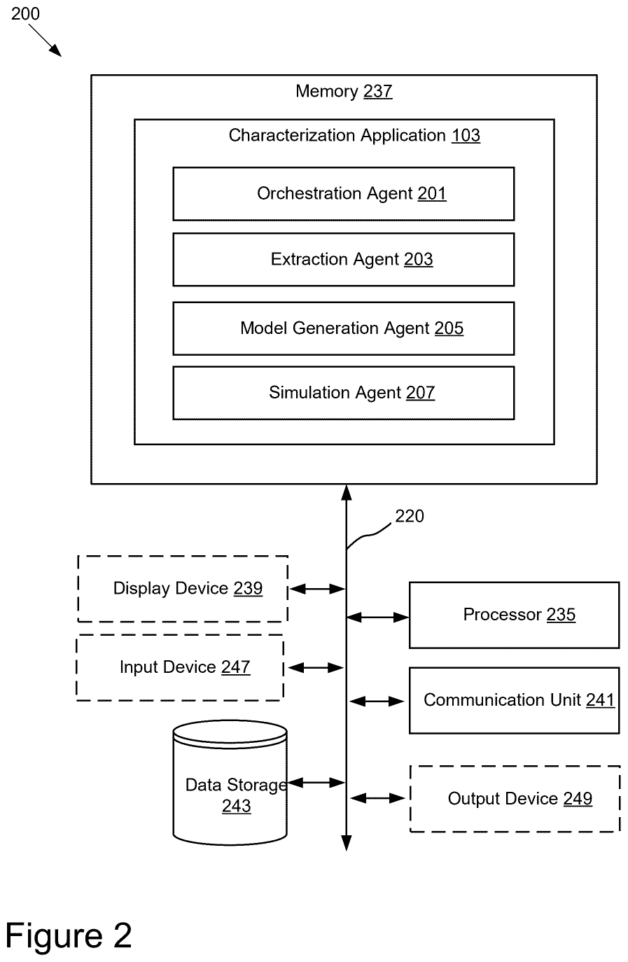

FIG. 2 shows a block diagram illustrating one embodiment of a computing device 200 including a characterization application 103. The computing device 200 may also include a processor 235, a memory 237, a communication unit 241, data storage 243, display device 239, input device 247, and output device 249 according to some examples. The components of the computing device 200 are communicatively coupled by a bus 220. In some embodiments, the computing device 200 may be the client device 115, the characterization server 101, or a combination of the client device 115 and the characterization server 101. In such embodiments where the computing device 200 is the client device 115 or the characterization server 101, it should be understood that the client device 115, and the characterization server 101 may include other components not shown in FIG. 2.

The processor 235 may execute software instructions by performing various input/output, logical, and/or mathematical operations. The processor 235 may be physical and/or virtual, and may include a single processing unit or a plurality of processing units and/or cores. In some implementations, the processor 235 may be capable of generating and providing electronic display signals to a display device, supporting the display of images, capturing and transmitting images, performing complex tasks including various types of feature extraction and sampling, etc. In some implementations, the processor 235 may be coupled to the memory 237 via the bus 220 to access data and instructions therefrom and store data therein. The bus 220 may couple the processor 235 to the other components of the computing device 200 including, for example, the communication unit 241, and the data storage 243. It will be apparent to one skilled in the art that other processors, operating systems, sensors, displays and physical configurations are possible.

The memory 237 may store and provide access to data for the other components of the computing device 200. The memory 237 may be included in a single computing device or distributed among a plurality of computing devices as discussed elsewhere herein. In some implementations, memory 237 may store instructions and/or data that may be executed by processor 235. The instructions and/or data may include code for performing the techniques described herein. For example, in one embodiment, memory 237 may store the characterization application 103. The memory 237 is also capable of storing other instructions and data, including, for example, an operating system, hardware drivers, other software applications, databases, etc. The memory 237 may be coupled to the bus 220 for communication with the processor 235 and the other components of the computing device 200.

The memory 237 may include one or more non-transitory computer-usable (e.g., readable, writeable) device, dynamic random access memory (DRAM) device, a static random access memory (SRAM) device, an embedded memory device, a discrete memory device (e.g., a PROM, FPROM, ROM), a hard disk drive, an optical disk drive, or other mediums, which can be any tangible apparatus or device that can contain, store, communicate, or transport instructions, data, computer programs, software, code, routines, etc., for processing by or in connection with the processor 235. It should be understood that the memory 237 may be a single device or may include multiple types of devices and configurations.

The communication unit 241 is hardware for receiving and transmitting data by linking the processor 235 to the network 105 and other processing systems. The communication unit 241 receives data such as requests from the client device 115 and transmits the requests to the orchestration agent 201, for example to characterize and validate an electronic component. In some embodiments, the orchestration agent 201 may be configured to manage dataflow and inter-agent dialogue using semantic tokens. The communication unit 241 also transmits information including recognition results to the client device 115 for display, for example, in response to a request to characterize and validate an electronic component. The communication unit 241 is coupled to the bus 220. In one embodiment, the communication unit 241 may include a port for direct physical connection to the client device 115 or to another communication channel. For example, the communication unit 241 may include an RJ45 port or similar port for wired communication with the client device 115. In another embodiment, the communication unit 241 may include a wireless transceiver for exchanging data with the client device 115 or any other communication channel using one or more wireless communication methods, such as IEEE 802.11, IEEE 802.16, Bluetooth® or another suitable wireless communication method.

In yet another embodiment, the communication unit 241 may include a cellular communications transceiver for sending and receiving data over a cellular communications network such as via short messaging service (SMS), multimedia messaging service (MMS), hypertext transfer protocol (HTTP), direct data connection, WAP, e-mail or another suitable type of electronic communication. The communication unit 241 may also provide other conventional connections to the network 105 for distribution of files and/or media objects using standard network protocols such as TCP/IP, HTTP, HTTPS and SMTP as will be understood to those skilled in the art.

The data storage 243 is a non-transitory memory that stores data for providing the functionality described herein. The data storage 243 may be a non-volatile memory or similar permanent storage device and media including a hard disk drive, a flash memory device, or some other mass storage device for storing information on a more permanent basis. In the illustrated embodiment, the data storage 243 is communicatively coupled to the bus 220. The data storage 243 may store data for characterizing and validating an electronic component and/or the results of the characterization and validation along with other functionality as described herein. For example, the data storage 243 may store an electronic component data sheet and the models generated from the data sheet.

In the illustrated embodiment, the display device 239 may be a screen for displaying a preview image or a user interface. The display device 239 may be incorporated into client device 115 or other device capable of being configured with a display screen.

In the illustrated embodiments, the input device 247 may be a device capable of capturing and/or receiving user input, including audio, video, images, text, or other input data. The input device 247 may be a stand-alone device or configured to be part of a client device 115. The input device 247 may be configured to connect to the processor 235 and data storage 243 to receive and send information from the characterization application 103. While the foregoing embodiments are described for the input device 247, it should be understood that the input device 247 may comprise any suitable combination of input devices and/or other suitable input devices capable of providing the benefit described herein.

In the illustrated embodiment, the output device 249, may be any device capable of producing an output to a user. The output device 249 may be a monitor or another output that is capable of being observed by a user.

In some embodiments, the characterization application 103 may include an orchestration agent 201, an extraction agent 203, a model generation agent 205, and a simulation agent 207. It should be noted that while the example of FIG. 2 depicts a particular number of agents, the functionality described herein may be performed by fewer or more agents in various combinations and the separation of tasks herein is simply to facilitate description. Additionally, the agents may be interoperable and modular, allowing substitution, stacking, or fine-tuning without retraining the system as a whole. The orchestration agent 201 may include software and/or logic to control the operation of the other components of the characterization application 103 to perform the methods described below. The orchestration agent 201 may also include software and/or logic to provide the functionality for handling communications between the characterization application 103 and other components of the computing device 200 as well as between the components of the characterization application 103. Each agent may operate using a task-specific mini-language tailored to its function (e.g., SPICE circuit construction, curve modeling, clustering). The orchestration agent 201 enables communication between other agents by implementing a domain-specific language that defines parametric designs, sweeps, and topologies using semantic tokens. This communication grammar enables the various agents to reason abstractly about circuit configuration without resorting to natural language. In some implementations, the orchestration agent 201 is stored in the memory 237 and is accessible and executable by the processor 235.

In some embodiments, the orchestration agent 201 sends and receives data, via the communication unit 241, to and from one or more of the client device 115 and the characterization server 101. For example, the orchestration agent 201 receives, via the communication unit 241, a request to characterize and validate an electronic component from a client device 115 and sends the data, including a component data sheet, to the extraction agent 203. In another example, the orchestration agent 201 receives characterization data from the extraction agent 203 and sends the data to model generation agent 205 for generating a circuit simulator model (e.g., a SPICE model) of the electronic component.

The extraction agent 203 may include software and/or logic to provide the functionality for extracting graphical curve and/or other data from an electronic component data sheet and providing results to other components of characterization application 103. In some embodiments, the extraction agent 203 is a set of instructions executable by the processor 235. In some implementations, the extraction agent 203 is stored in the memory 237 and is accessible and executable by the processor 235.

The model generation agent 205 may be configured to generate a circuit simulator model. This may include, for example, interpreting symbolic circuit fragments and constructing circuit simulator models based on extracted data from extraction agent 203. In some embodiments, the model generation agent 205 is a set of instructions executable by the processor 235. In some implementations, the model generation agent 205 is stored in the memory 237 and is accessible and executable by the processor 235.

The simulation agent 207 may be configured to iteratively generate test conditions to mirror or extend the circuit simulator models generated by model generation agent 205. Simulation agent 207 may further be configured to perform simulations based on the circuit simulator model, interpret the simulation results, and perform self-supervised correction of the circuit simulator model. In some embodiments, the simulation agent 207 is a set of instructions executable by the processor 235. In some implementations, the simulation agent 207 is stored in the memory 237 and is accessible and executable by the processor 235.

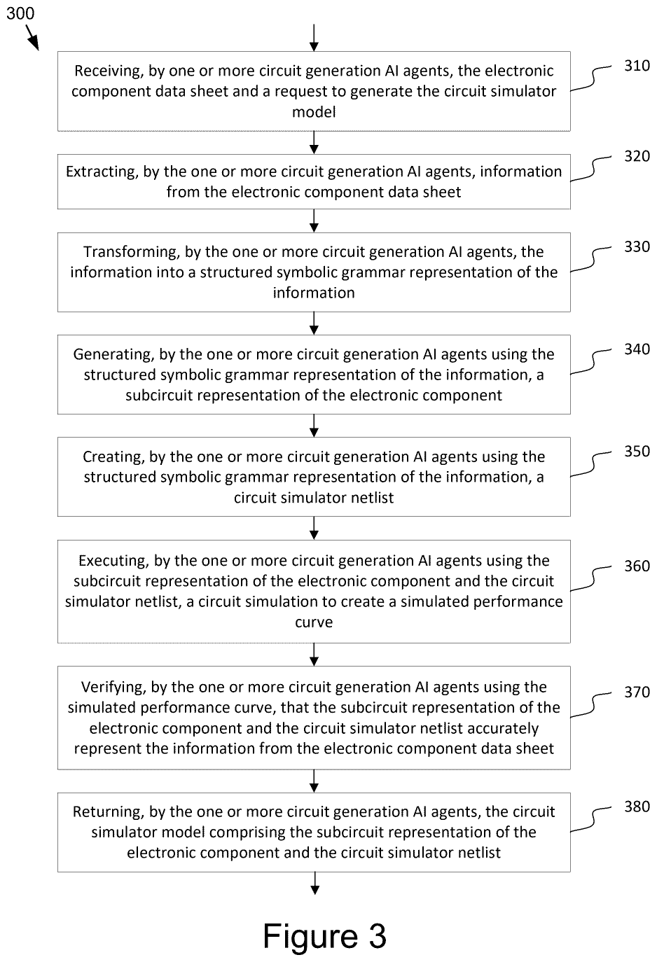

FIG. 3 is a flowchart depicting an example method 300 for generating a circuit simulator model of an electronic component from an electronic component data sheet. At 310, the method includes receiving, by one or more circuit generation AI agents (e.g., orchestration agent 201), the electronic component data sheet and a request to generate the circuit simulator model.

At 320, the method includes extracting, by the one or more circuit generation AI agents (e.g., extraction agent 203), information from the electronic component data sheet. As described in U.S. Provisional Patent Application No. 63/792,155, extracting information from the electronic component data sheet may include extracting, by the one or more circuit generation AI agents (e.g., extraction agent 203), performance curve image data; applying, by the one or more circuit generation AI agents (e.g., extraction agent 203), a curve fitting algorithm to the performance curve image data; recognizing, by the one or more circuit generation AI agents (e.g., extraction agent 203), axis labels of the performance curve image data; and interpolating, by the one or more circuit generation AI agents (e.g., extraction agent 203), data points on the performance curve. More specifically, extracting information from the electronic component data sheet may include using PDF parsing libraries to identify and extract embedded image content from datasheets; applying an align-sweeping algorithm to detect colored traces (supports both vector (SVG) and raster formats); using OCR (e.g., Tesseract) to detect and label axes and infer measurement units; and projecting candidate curves (e.g., cubic Bezier or NURBS) and uses iterative control point fitting to minimize error.

The extraction agent 203 may further employ a multi-layered approach to extract and optimize graphical curves, including Bresenham-based tracing, color matching and gradient interpolation, quantization and fuzzy binning, recursive curve fitting, and reinforcement feedback optimization. Bresenham-based tracing may include, for example, an initial vectorization phase using Bresenham's line algorithm to detect pixel-aligned curve segments in raster data. Color matching and gradient interpolation may include, for example, identifying target curves based on RGB and HSL deltas and using color range gradients to interpolate likely path regions. Injective transformations with Euclidization may be used to normalize axis warping or scaling artifacts. Quantization and fuzzy binning may include, for example, applying histogram-based quantization and fuzzy logic binning to isolate clusters of pixel traces and suppress noise. Recursive curve fitting may include, for example, iteratively applying cubic Bézier and NURBS-based approximations to refine control points through projective curve projections and residual analysis. Reinforcement feedback optimization may include, for example, performing iterative masking, knot, and weight refinement using feedback from error metrics, enabling adaptive learning to improve time-to-fit. This intelligent fitting method yields high-precision, simulation-ready models and significantly reduces manual tuning or curve redrawing.

At 330, the method includes transforming, by the one or more circuit generation AI agents (e.g., orchestration agent 201), the information into a structured symbolic grammar (e.g., NCScript) representation of the information. In various embodiments, the structured symbolic grammar allows the agents to express symbolic elements (e.g., MOSFET, RLC blocks, etc.), topologies (e.g., mesh, star, cascaded, etc.), and functional constraints (e.g., biasing, clamping, feedback, etc.) of the electronic component.

At 340, the method includes generating, by the one or more circuit generation AI agents (e.g., model generation agent 205) using the structured symbolic grammar representation of the information, a subcircuit representation of the electronic component. In various embodiments, the subcircuit representation may include node and mesh networks and PWL input sources.

At 350, the method includes creating, by the one or more circuit generation AI agents (e.g., model generation agent 205) using the structured symbolic grammar representation of the information, a circuit simulator netlist. For example, the netlist may be a SPICE, LTSpice, Verilog, Veriolg-A, HSPICE, or similar netlist.

At 360, the method includes executing, by the one or more circuit generation AI agents (e.g., simulation agent 207) using the subcircuit representation of the electronic component and the circuit simulator netlist, a circuit simulation to create a simulated performance curve.

At 370, the method includes verifying, by the one or more circuit generation AI agents (e.g., simulation agent 207) using the simulated performance curve, that the subcircuit representation of the electronic component and the circuit simulator netlist accurately represent the information from the electronic component data sheet. In some embodiments, simulation agent 207 may perform clustering of simulation outputs to form deterministic similarity groupings. The clustering methods used by simulation agent 207 may include, or example, agglomerative hierarchical clustering, DBSCAN, or KMeans clustering. These similarity groupings enable cross-referencing and substitution between different electronic components.

At 380, the method includes returning, based on the request to generate the circuit simulator model, by the one or more circuit generation AI agents, the circuit simulator model comprising the subcircuit representation of the electronic component and the circuit simulator netlist.

The benefits of the foregoing include, but are not limited to, part selection and substitution driven by performance, not part number, improved SPICE validation over static models, and discovery of new component applications via semantic clustering. The simulation outputs may further be used to train embedding models, cluster similar devices, update taxonomy, and propose substitutions based on performance equivalence rather than manufacturer metadata.

In some embodiments, the output of may be used to design a printed circuit board using the modeled electronic components and cause the printed circuit board to be manufactured based on the design.

The foregoing description, for purpose of explanation, has been described with reference to various embodiments and examples. However, the illustrative discussions above are not intended to be exhaustive or to limit the invention to the precise forms disclosed. Many modifications and variations are possible in view of the above teachings. The various embodiments and examples were chosen and described in order to best explain the principles of the invention and its practical applications, to thereby enable others skilled in the art to utilize the innovative technology with various modifications as may be suited to the particular use contemplated. For instance, it should be understood that the technology described herein can be practiced without these specific details in some cases. Further, various systems, devices, and structures are shown in block diagram form in order to avoid obscuring the description. For instance, various implementations are described as having particular hardware, software, and user interfaces. However, the present disclosure applies to any type of computing device that can receive data and commands, and to any peripheral devices providing services.

In some instances, various implementations may be presented herein in terms of algorithms and symbolic representations of operations on data bits within a computer memory. An algorithm is here, and generally, conceived to be a self-consistent set of operations leading to a desired result. The operations are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the following discussion, it is appreciated that throughout this disclosure, discussions utilizing terms such as “processing,” “computing,” “calculating,” “determining,” “displaying,” or the like, refer to the action and methods of a computer system that manipulates and transforms data represented as physical (electronic) quantities within the computer system's registers and memories into other data similarly represented as physical quantities within the computer system memories or registers or other such information storage, transmission or display devices.

A data processing system suitable for storing and/or executing program code, such as the computing system and/or devices discussed herein, may include at least one processor coupled directly or indirectly to memory elements through a system bus. The memory elements can include local memory employed during actual execution of the program code, bulk storage, and cache memories that provide temporary storage of at least some program code in order to reduce the number of times code must be retrieved from bulk storage during execution. Input or I/O devices can be coupled to the system either directly or through intervening I/O controllers. The data processing system may include an apparatus may be specially constructed for the required purposes, or it may comprise a general-purpose computer selectively activated or reconfigured by a computer program stored in the computer.

The foregoing description has been presented for the purposes of illustration and description. It is not intended to be exhaustive or to limit the specification to the precise form disclosed. Many modifications and variations are possible in light of the above teaching. It is intended that the scope of the disclosure be limited not by this detailed description, but rather by the claims of this application. As will be understood by those familiar with the art, the specification may be embodied in other specific forms without departing from the spirit or essential characteristics thereof. Likewise, the particular naming and division of the modules, routines, features, attributes, methodologies and other aspects may not be mandatory or significant, and the mechanisms that implement the specification or its features may have different names, divisions, and/or formats.

Furthermore, the modules, routines, features, attributes, methodologies and other aspects of the disclosure can be implemented as software, hardware, firmware, or any combination of the foregoing. The technology can also take the form of a computer program product accessible from a computer-usable or computer-readable medium providing program code for use by or in connection with a computer or any instruction execution system. Wherever a component, an example of which is a module or engine, of the specification is implemented as software, the component can be implemented as a standalone program, as part of a larger program, as a plurality of separate programs, as a statically or dynamically linked library, as a kernel loadable module, as firmware, as resident software, as microcode, as a device driver, and/or in every and any other way known now or in the future. Additionally, the disclosure is in no way limited to implementation in any specific programming language, or for any specific operating system or environment. Accordingly, the disclosure is intended to be illustrative, but not limiting, of the scope of the subject matter set forth in the following claims.

What is claimed is:

1. A method for generating a circuit simulator model of an electronic component from an electronic component data sheet, the method comprising:
receiving, by one or more circuit generation AI agents, the electronic component data sheet and a request to generate the circuit simulator model;
extracting, by the one or more circuit generation AI agents, information from the electronic component data sheet;
transforming, by the one or more circuit generation AI agents, the information into a structured symbolic grammar representation of the information;
generating, by the one or more circuit generation AI agents using the structured symbolic grammar representation of the information, a subcircuit representation of the electronic component;
creating, by the one or more circuit generation AI agents using the structured symbolic grammar representation of the information, a circuit simulator netlist;
executing, by the one or more circuit generation AI agents using the subcircuit representation of the electronic component and the circuit simulator netlist, a circuit simulation to create a simulated performance curve;
verifying, by the one or more circuit generation AI agents using the simulated performance curve, that the subcircuit representation of the electronic component and the circuit simulator netlist accurately represent the information from the electronic component data sheet; and
returning, by the one or more circuit generation AI agents, the circuit simulator model comprising the subcircuit representation of the electronic component and the circuit simulator netlist.

2. The method of claim 1, further comprising:
receiving a request to include the electronic component in a printed circuit board circuit design; and
causing the manufacture of a printed circuit board based on the printed circuit board circuit design.

3. The method of claim 1, further comprising clustering, by the one or more circuit generation AI agents, simulation outputs to form deterministic similarity groupings, wherein the similarity groupings enable cross-referencing and substitution between different electronic components.

4. The method of claim 1, further comprising iteratively refining, by the one or more circuit generation AI agents, symbolic models using simulation error provided by a feedback loop and self-supervised learning.

5. The method of claim 1, wherein the subcircuit representation includes node and mesh networks and PWL input sources.

6. The method of claim 1, wherein the structured symbolic grammar is capable of expressing symbolic elements, topologies, and functional constraints of the electronic component.

7. The method of claim 1, wherein extracting the information from the electronic component data sheet further comprises:
extracting, by the one or more circuit generation AI agents, performance curve image data;
applying, by the one or more circuit generation AI agents, a curve fitting algorithm to the performance curve image data;
recognizing, by the one or more circuit generation AI agents, axis labels of the performance curve image data; and
interpolating, by the one or more circuit generation AI agents, data points on the performance curve.

8. A system for generating a circuit simulator model of an electronic component from an electronic component data sheet, the system comprising:
one or more processors; and
one or more memories storing instructions that, when executed by the one or more processors in response to a request to generate the circuit simulation model, cause one or more circuit generation AI agents to perform operations including:
extracting information from the electronic component data sheet;
transforming the information into a structured symbolic grammar representation of the information;
generating, using the structured symbolic grammar representation of the information, a subcircuit representation of the electronic component;
creating, using the structured symbolic grammar representation of the information, a circuit simulator netlist;
executing, using the subcircuit representation of the electronic component and the circuit simulator netlist, a circuit simulation to create a simulated performance curve;
verifying, using the simulated performance curve, that the subcircuit representation of the electronic component and the circuit simulator netlist accurately represent the information from the electronic component data sheet; and
returning the circuit simulator model comprising the subcircuit representation of the electronic component and the circuit simulator netlist.

9. The system of claim 8, wherein the instructions, when executed by the one or more processors, further cause the system to perform operations including:
receiving a request to include the electronic component in a printed circuit board circuit design; and
causing the manufacture of a printed circuit board based on the printed circuit board circuit design.

10. The system of claim 8, wherein the instructions, when executed by the one or more processors, further cause the one or more circuit generation AI agents to perform operations including clustering simulation outputs to form deterministic similarity groupings, wherein the similarity groupings enable cross-referencing and substitution between different electronic components.

11. The system of claim 8, wherein the instructions, when executed by the one or more processors, further cause the one or more circuit generation AI agents to perform operations including iteratively refining symbolic models using simulation error provided by a feedback loop and self-supervised learning.

12. The system of claim 8, wherein the subcircuit representation includes node and mesh networks and PWL input sources.

13. The system of claim 8, wherein the structured symbolic grammar is capable of expressing symbolic elements, topologies, and functional constraints of the electronic component.

14. The system of claim 8, wherein extracting information from the electronic component data sheet further comprises:
extracting performance curve image data;
applying a curve fitting algorithm to the performance curve image data;
recognizing axis labels of the performance curve image data; and
interpolating data points on the performance curve.

15. A method comprising:
receiving, by one or more circuit generation AI agents, a request to generate a circuit simulator model of an electronic component, the request including an electronic component data sheet;
extracting, by the one or more circuit generation AI agents, information from the electronic component data sheet;
generating, by the one or more circuit generation AI agents, a subcircuit representation and a circuit simulator model of the electronic component using a structured symbolic grammar representation of information extracted from the electronic component data sheet;
executing, by the one or more circuit generation AI agents using the subcircuit representation of the electronic component and the circuit simulator model, a circuit simulation to create a simulated performance curve;
verifying, by the one or more circuit generation AI agents using the simulated performance curve, that the subcircuit representation of the electronic component and the circuit simulator model accurately represent the information from the electronic component data sheet; and
returning, by the one or more circuit generation AI agents, the circuit simulator model and the subcircuit representation of the electronic component.

16. The method of claim 15, further comprising:
receiving a request to include the electronic component in a printed circuit board circuit design; and
causing the manufacture of a printed circuit board based on the printed circuit board circuit design.

17. The method of claim 15, further comprising clustering, by the one or more circuit generation AI agents, simulation outputs to form deterministic similarity groupings, wherein the similarity groupings enable cross-referencing and substitution between different electronic components.

18. The method of claim 15, further comprising iteratively refining, by the one or more circuit generation AI agents, symbolic models using simulation error provided by a feedback loop and self-supervised learning.

19. The method of claim 15, wherein the structured symbolic grammar is capable of expressing symbolic elements, topologies, and functional constraints of the electronic component.

20. The method of claim 15, wherein extracting information from the electronic component data sheet further comprises:
extracting, by the one or more circuit generation AI agents, performance curve image data;
applying, by the one or more circuit generation AI agents, a curve fitting algorithm to the performance curve image data;
recognizing, by the one or more circuit generation AI agents, axis labels of the performance curve image data; and
interpolating, by the one or more circuit generation AI agents, data points on the performance curve.
